(19) United States
(12) Patent Application Publication
(10) Pub. No.: US 2015/0311362 A1
(43) Pub. Date: Oct. 29, 2015

(54) TRANSPARENT-CONDUCTIVE-FILM LAMINATE, MANUFACTURING METHOD THEREFOR, THIN-FILM SOLAR CELL, AND MANUFACTURING METHOD THEREFOR

(71) Applicant: SUMITOMO METAL MINING CO., LTD., Tokyo (JP)

(72) Inventors: Kentaro SOGABE, Tokyo (JP); Yasunori YAMANOBE, Tokyo (JP); Fumihiko MATSUMURA, Tokyo (JP)

(21) Appl. No.: 14/441,316

(22) PCT Filed: Oct. 11, 2013
(86) PCT No.: PCT/JP2013/077829

§ 371 Date: May 7, 2015

(30) Foreign Application Priority Data
Nov. 7, 2012 (JP) 2012-245390

(51) Int. Cl. H01L 31/0224; H01J 37/34; C23C 14/34; C23C 14/08; H01L 31/18; C09D 5/24

(52) U.S. Cl. CPC H01L 31/022483; H01L 31/1884; C09D 5/24; H01L 31/022466; C23C 14/34; C23C 14/086; H01J 37/3429

(57) ABSTRACT

The present invention provides a transparent-conductive-film laminate and a manufacturing method therefor, and provides a thin-film solar cell using the transparent-conductive-film laminate and a manufacturing method for the thin-film solar cell. The transparent-conductive-film laminate has a structure, the structure including an indium-oxide-based transparent conductive film (I) with a surface roughness (Ra) of not more than 1.0 nm formed on a translucent substrate, and a zinc-oxide-based transparent conductive film (II) formed on the indium-oxide-based transparent conductive film (I); and has a surface roughness (Ra) of not less than 30 nm as a laminate, a haze ratio of not less than 8%, a resistance value of not more than 30 Ω/sq., and an average absorptivity with respect to light in a wavelength range of 400 nm to 1200 nm of not more than 15%.

### FIELD OF THE INVENTION

The present invention relates to a transparent-conductive-film laminate and a manufacturing method therefor, the transparent-conductive-film laminate being useful as a surface electrode at the time of the manufacture of a high-efficiency silicon-based thin-film solar cell, having a low optical absorption loss, and having an excellent effect of optical confinement, and relates to a thin-film solar cell and a manufacturing method therefor. The present application claims priority based on Japanese Patent Application No. 2012-245390 filed in Japan on Nov. 7, 2012. The total contents of the patent application are incorporated by reference into the present application.

### BACKGROUND ART

A transparent conductive film having high conductivity and high transmittance in a visible light region has been used for electrodes of solar cells, liquid crystal display elements, and other various light-receiving elements, and furthermore, has been used as a heat reflecting film for automobile windows and architectures, an antistatic film, and a transparent heating element used for defogging a freezing showcase.

As a transparent conductive film, a tin-oxide-based (SnO₂) thin film, a zinc-oxide-based (ZnO) thin film, and an indium-oxide-based (In₂O₃) thin film are known. A material (ATO) that contains antimony as a dopant and a material (FTO) that contains fluorine as a dopant have been used as tin-oxide-based thin films. A material (AZO) that contains aluminum as a dopant and a material (GZO) that contains gallium as a dopant have been used as zinc-oxide-based thin films.

A transparent conductive film which has been most commonly industrially used is an indium-oxide-based thin film, and especially, an indium-oxide thin film that contains tin as a dopant is called an ITO (Indium-Tin-Oxide) film, and an ITO film with particularly low resistance can be easily obtained, therefore, the film has been widely used.

In recent years, global environmental problems due to an increase in carbon dioxide and the like and problems of a steep rise in fossil fuel prices have been highlighted, and accordingly, a thin-film solar cell, which can be manufactured at relatively low cost, has been attracting attention. A thin-film solar cell that generates electricity by light incident from a translucent substrate such as a glass substrate generally includes a transparent conductive film, at least one semiconductor thin-film photoelectric conversion unit, and a back surface electrode, in which the transparent conductive film, the semiconductor thin-film photoelectric conversion unit, and the back surface electrode are laminated in that order on a translucent substrate. Abundant silicon resources exist, and therefore, among thin-film solar cells, a silicon-based thin-film solar cell in which a silicon-based thin-film is used for a photoelectric conversion unit (an optical absorption layer) has been ahead of others in being put to practical use, and the research and development of the silicon-based thin-film solar cell have been more and more actively carried out.

Moreover, the variety of silicon-based thin-film solar cells has been increased, and, besides a conventional amorphous thin-film solar cell that uses an amorphous thin-film such as amorphous silicon for an optical absorption layer, a microcrystalline thin-film solar cell that uses a microcrystalline thin film formed of a mixture of amorphous silicon and microcrystal silicon and a crystalline thin-film solar cell that uses a crystalline thin film formed of crystalline silicon have been developed, and a hybrid thin-film solar cell obtained by laminating these solar cells have been also put in practical use.

As for such photoelectric conversion unit or such thin-film solar cell, regardless of whether p-type and n-type conductive semiconductor layers included in the photoelectric conversion unit or the thin-film solar cell are amorphous, crystalline, or microcrystalline, a photoelectric conversion unit or a thin-film solar cell that includes an amorphous photoelectric conversion layer as a main part of the unit or the cell is called an amorphous unit or an amorphous thin-film solar cell; a photoelectric conversion unit or a thin-film solar cell that includes a crystalline photoelectric conversion layer is called a crystalline unit or a crystalline thin-film solar cell; and a photoelectric conversion unit or a thin-film solar cell that includes a microcrystalline photoelectric conversion layer is called a microcrystalline unit or a microcrystalline thin-film solar cell.

Meanwhile, a transparent conductive film has been used for a transparent surface electrode of a thin-film solar cell, and, in order to effectively confine the light incident from a translucent substrate side within a photoelectric conversion unit, a large number of fine projections-and-depressions are usually formed in the surface of the transparent conductive film.

As an index that indicates the degree of the roughness of a transparent conductive film, a haze ratio is used. The haze ratio corresponds to a value obtained in such a manner that, among lights that penetrate a translucent substrate having a transparent conductive film when lights from a specific light source are made to enter the translucent substrate, scattered light components whose optical paths are bent are divided by all light components, and usually, the haze ratio is measured using the illuminant C containing visible light. Generally, a larger difference in height between projections and depressions or a larger interval between projections of projections-and-depressions causes a haze ratio to be made higher and the light incident within a photoelectric conversion unit to be effectively confined therein, in other words, excellent effect of optical confinement is achieved.

Regardless of whether a thin-film solar cell is a thin-film solar cell including amorphous silicon, crystalline silicon, or microcrystalline silicon as a single layer of an optical absorption layer, or the foregoing hybrid thin-film solar cell, if the haze ratio of a transparent conductive film can be made higher and optical confinement can be sufficiently performed, then a high short-circuit current density (Jsc) can be achieved and a thin-film solar cell having high conversion efficiency can be manufactured.

To achieve the foregoing object, a metal oxide material that contains tin oxide as a main component and produced by a thermal CVD method is known as a transparent conductive film having a high haze ratio, and has been commonly utilized as a transparent electrode of a thin-film solar cell.

A photoelectric conversion unit formed on the surface of a transparent conductive film is generally manufactured by a high frequency plasma CVD method, and as a source gas used in such a case, a silicon-containing gas, such as SiH₄ or Si₂H₆, or a mixture of H₂ and the silicon-containing gas is used. In addition, as a dopant gas for forming a p-type or n-type layer in the photoelectric conversion unit, a gas, such as B₂H₆ or PH₃, is preferably used. The formation conditions of the photoelectric conversion unit are preferably a substrate temperature of not less than 100° C. and not more than 250° C. (however, for a p-type amorphous silicon carbide layer 3p, not more than 180° C.), a pressure of not less than 30 Pa and not more than 1500 Pa, and a high frequency power density of not less than 0.01 W/cm² and not more than 0.5 W/cm².

At the time of thus manufacturing a photoelectric conversion unit, a higher formation temperature accelerates the reduction of a metal oxide by hydrogen present, and hence, in the case of a transparent conductive film that contains tin oxide as a main component, the hydrogen reduction causes a loss in transparency of the film. The use of such transparent conductive film having poor transparency prevents a thin-film solar cell having high conversion efficiency from being realized.

Likewise, also in a transparent conductive film that contains indium oxide as a main component, this hydrogen reduction causes a loss in transparency of the film. Particularly, in the case of using an indium-oxide-based transparent conductive film, the hydrogen reduction causes a loss in transparency to the extent that the film is made black, and hence, it is very difficult to use the indium-oxide-based transparent conductive film as a surface electrode of a thin-film solar cell.

As a method for preventing a transparent conductive film containing tin oxide as a main component from being reduced by hydrogen, Non-patent document 1 proposes a method for thinly forming a zinc oxide film with excellent reduction resistance by a sputtering method on a transparent conductive film made of tin oxide, having a high degree of roughness, and formed by a thermal CVD method. Zinc oxide contains zinc and oxygen, which are strongly bonded to each other, and zinc oxide is highly resistant to hydrogen reduction, and therefore, such structure allows the transparency of the transparent conductive film to be kept high.

However, to obtain a transparent conductive film having the foregoing structure, the film needs to be deposited by using the two types of methods in combination, thereby causing high costs, which is not practical. Furthermore, it has been considered that a technique of manufacturing a lamination film formed of a tin-oxide-based transparent conductive film and a zinc-oxide-based transparent conductive film only by a sputtering method is impracticable because, for example, a tin-oxide-based transparent conductive film having a high degree of transparency cannot be manufactured by a sputtering method.

On the other hand, Non-patent document 2 proposes a method of obtaining a transparent conductive film using a sputtering method, the transparent conductive film containing zinc oxide as a main component, having surface roughness and having a high haze ratio. This method is such that, using a sintered compact target of zinc oxide to which 2 wt % of Al₂O₃ is added, sputtering deposition is performed at a high gas pressure of not less than 3 Pa and not more than 12 Pa and a substrate temperature of not less than 200° C. and not more than 400° C. However, in this method, the deposition is performed by supplying an electric power of DC 80 W to a 6-inchφ target, and the input power density to the target is very low, namely, 0.442 W/cm². Therefore, the deposition rate is very low, namely, not less than 14 nm/min and not more than 35 nm/min, and hence, this method is industrially impractical.

Non-patent document 3 discloses a method for manufacturing a transparent conductive film, the method being such that a transparent conductive film containing zinc oxide as a main component, being produced by a conventional sputtering method and having a low surface-roughness is obtained, and then, the surface of the film is etched by acid to be rougher, whereby a transparent conductive film having a high haze ratio is manufactured. However, this method has problems that, in a drying step, a film is manufactured by a sputtering method as a vacuum process, and then dried by acid etching in the atmosphere, and again, a semiconductor layer needs to be formed by a CVD method of the drying step, whereby the step is thus more complicated and causes higher manufacturing costs.

To solve the foregoing problems in Non-patent document 2 and Non-patent document 3, Patent document 1 proposes a method, the method being such that a zinc-oxide-based transparent conductive film that has surface roughness to increase optical conversion efficiency as a solar cell is obtained without a wet etching step and only by a sputtering method using hydrogen gas introduction or the like.

However, in the method of Patent document 1, deposition is performed using a zinc oxide sintered compact target by a RF magnetron sputtering method at a gas pressure of not less than 0.1 Pa and not more than 4 Pa and a substrate temperature of not less than 100° C. and not more than 500° C. Through the inventors' study, it has been found that, compared with a DC magnetron sputtering method, an RF magnetron sputtering method causes a deposition rate to be extremely lower, and hence, particle growth tends to be accelerated by substrate heating, and, as a result, a transparent electrode film having surface roughness can be obtained, but, the method is industrially impractical. In addition, the obtained transparent conductive film is a zinc-oxide-based single layer and has surface roughness, but, in this case, a considerable film thickness is required for achieving conductivity necessary as a surface electrode, and therefore, it cannot be that the method is industrially useful.

Among zinc-oxide-based transparent conductive film materials, as for AZO, which contains aluminum as a dopant, Patent document 2 proposes a method of manufacturing an AZO transparent conductive film, in which, using a target that contains zinc oxide as a main component and has aluminum oxide mixed therein, a C-axis oriented AZO transparent conductive film is manufactured by a direct-current magnetron sputtering method. However, in this case, if direct-current sputtering deposition is performed in a state in which an electric power density to be supplied to the target is increased in order to perform the deposition at high speed, an arc discharge (abnormal discharge) frequently occurs. The occurrence of an arc discharge in a production process on deposition lines causes a defect of a film and a failure to obtain a film of predetermined thickness, whereby it becomes impossible to stably manufacture a high-grade transparent conductive film.

Therefore, the applicant proposes a sputtering target that contains zinc oxide as a main component, gallium oxide mixed therein, and a third element (Ti, Ge, Al, Mg, In, Sn) added thereto to reduce an abnormal discharge (see Patent document 3). Here, a GZO sintered compact that contains gallium as a dopant includes: as a major constituent phase, a ZnO phase in which a solid solution is formed with not less than 2% by weight of at least one kind selected from the group consisting of Ga, Ti, Ge, Al, Mg, In, and Sn; and, as other constituent phase, a ZnO phase in which a solid solution is not formed with at least one kind selected from the foregoing group, and an intermediate compound phase that is represented by ZnGa₂O₄ (a spinel phase).

However, such GZO target to which a third element such as aluminum is added can reduce but cannot completely prevent the abnormal discharge described in Patent document 2. Only one occurrence of the abnormal discharge in continuous lines for deposition makes a product at the time of the deposition into a defective product, whereby manufacturing yield is affected.

To solve this problem, the applicant proposes an oxide sintered compact for targets that contains zinc oxide as a main component, and further contains aluminum and gallium as additive elements, in which the content of aluminum and gallium is optimized and also the kind and the composition of a crystal phase produced during baking, especially the composition of a spinel crystal phase are optimized, whereby there is achieved the oxide sintered compact for targets that hardly forms particles even if deposition is continuously performed for a long time by a sputtering apparatus, and that causes no abnormal discharge even under a high DC power supplied (see Patent document 4).

The use of such zinc-oxide-based sintered compact enables the deposition of a transparent conductive film having a lower resistance, a higher transmittance, and a higher quality than the conventional films. However, in recent years, a solar cell of higher conversion efficiency has been desired, and accordingly, a higher quality transparent conductive film that is applicable to the solar cell has been required.

### PRIOR-ART DOCUMENTS

### Patent Documents

Patent document 1: WO2010/038954
Patent document 2: Japanese Patent Application Laid-Open No. S62-122011
Patent document 3: Japanese Patent Application Laid-Open No. H10-306367
Patent document 4: Japanese Patent No. 4231967

### Non-Patent Documents

Non-patent document 1: K. Sato et al., “Hydrogen Plasma Treatment of ZnO-Coated TCO Films”, Proc. of 23th IEEE Photovoltaic Specialists Conference, Louisville, 1993, pp. 855-859.
Non-patent document 2: T. Minami, et al., “Large-Area Milkey Transparent Conducting Al-Doped ZnO Films Prepared by Magnetron Sputtering”, Japanese Journal of Applied Physics, [31] (1992), pp. L1106-1109.
Non-patent document 3: J. Muller, et. al., Thin Solid Films, 392 (2001), p. 327.

### SUMMARY OF THE INVENTION

### Problems to be Solved by the Invention

In view of the foregoing circumstances, an object of the present invention is to provide a transparent-conductive-film laminate and a manufacturing method therefor, the transparent-conductive-film laminate being useful as a surface electrode at the time of the manufacture of a high-efficiency silicon-based thin-film solar cell, having low optical absorptivity, and having an excellent effect of optical confinement, and to provide a thin-film solar cell using the transparent-conductive-film laminate and a manufacturing method for the thin-film solar cell.

### Means to Solve the Problems

To solve the foregoing problems of the prior art, the inventors earnestly made a study and examined various transparent conductive film materials as a transparent conductive film to be used for a transparent surface electrode of a thin-film solar cell. As a result, the inventors found that a laminated structure in which an indium-oxide-based transparent conductive film (I) having controlled crystallinity and a controlled surface state is formed on a translucent substrate and a zinc-oxide-based transparent conductive film (II) having crystallinity being closely-packed and having excellent roughness characteristics is formed on the indium-oxide-based transparent conductive film (I) is a structure having a lower loss of optical absorption and having an excellent effect of optical confinement, and thus the inventors accomplished the present invention.

That is, a transparent-conductive-film laminate according to the present invention has a structure, the structure including; an indium-oxide-based transparent conductive film (I) with a surface roughness (Ra) of not more than 1.0 nm formed on a translucent substrate; and a zinc-oxide-based transparent conductive film (II) formed on the indium-oxide-based transparent conductive film (I), in which the transparent-conductive-film laminate has, as a laminate, a surface roughness (Ra) of not less than 30 nm, a haze ratio of not less than 8%, and a resistance value of not more than 30 Ω/sq., and has an average absorptivity with respect to light in a wavelength range of 400 nm to 1200 nm of not more than 15%.

A manufacturing method of a transparent-conductive-film laminate according to the present invention includes: a first deposition step of forming an indium-oxide-based transparent conductive film (I) having a film thickness of not less than 10 nm and not more than 300 nm on a translucent substrate by a sputtering method under conditions of a gas pressure of not less than 0.1 Pa and not more than 2.0 Pa and a substrate temperature of not more than 50° C.; and a second deposition step of forming a zinc-oxide-based transparent conductive film (II) having a film thickness of not less than 200 nm and not more than 1000 nm on the foregoing indium-oxide-based transparent conductive film (I) by a sputtering method under conditions of a gas pressure of not less than 0.1 Pa and not more than 2.0 Pa and a substrate temperature of not less than 200° C. and not more than 450° C.

A thin-film solar cell according to the present invention is a thin-film solar cell including a translucent substrate, and a transparent-conductive-film laminate, a photoelectric conversion layer unit, and a back surface electrode layer formed in that order on the translucent substrate, in which the transparent-conductive-film laminate has a structure, the structure including: an indium-oxide-based transparent conductive film (I) with a surface roughness (Ra) of not more than 1.0 nm formed on the translucent substrate; and a zinc-oxide-based transparent conductive film (II) formed on the indium-oxide-based transparent conductive film (I), and has, as a laminate, a surface roughness (Ra) of not less than 30 nm, a haze ratio of not less than 8%, and a resistance value of not more than 30 Wsq., and has an average absorptivity with respect to light in a wavelength range of 400 nm to 1200 nm of not more than 15%.

A manufacturing method for a thin-film solar cell according to the present invention is a manufacturing method for a thin-film solar cell, the thin-film solar cell including a translucent substrate, and a transparent-conductive-film laminate, a photoelectric conversion layer unit, and a back surface electrode layer formed in that order on the translucent substrate, in which the transparent-conductive-film laminate is formed by a transparent-conductive-film laminate formation step, the transparent-conductive-film laminate formation step including: a first deposition step of forming an indium-oxide-based transparent conductive film (I) having a film thickness of not less than 10 nm and not more than 300 nm on the translucent substrate by a sputtering method under conditions of a gas pressure of not less than 0.1 Pa and not more than 2.0 Pa and a substrate temperature of not more than 50° C.; and a second deposition step of forming a zinc-oxide-based transparent conductive film (II) having a film thickness of not less than 200 nm and not more than 1000 nm on the indium-oxide-based transparent conductive film (I) by a sputtering method under conditions of a gas pressure of not less than 0.1 Pa and not more than 2.0 Pa and a substrate temperature of not less than 200° C. and not more than 450° C.

### Effects of the Invention

According to the present invention, a laminated structure including an indium-oxide-based transparent conductive film (I) with a surface roughness (Ra) of not more than 1.0 nm formed on a translucent substrate and a zinc-oxide-based transparent conductive film (II) formed on the indium-oxide-based transparent conductive film (I) makes the crystallinity and the surface state of the indium-oxide-based transparent conductive film (I) to be controlled, whereby a transparent-conductive-film laminate having a lower loss of optical absorption and having an excellent effect of optical confinement can be provided.

Furthermore, the transparent-conductive-film laminate can be manufactured only by a low-gas-pressure sputtering method excellent for mass production, and the transparent-conductive-film laminate is not only excellent in conductivity and the like to be used for a transparent surface electrode of a thin-film solar cell, but also enables a cost reduction, compared to conventional transparent conductive films obtained by a thermal CVD method. Furthermore, not the use of a high gas pressure, RF magnetron sputtering, and the like, which are disadvantageous manufacturing conditions for mass production, but the use of DC magnetron sputtering allows a high-efficiency silicon-based thin-film solar cell to be provided inexpensively with a simple process, and is industrially very useful.

### BRIEF DESCRIPTION OF THE DRAWINGS

FIG. 1(A) is a SEM micrograph of a surface texture of a transparent-conductive-film laminate obtained by depositing a zinc-oxide-based transparent conductive film at a sputtering gas pressure of not less than 0.1 Pa and not more than 2.0 Pa, and FIG. 1(B) is a SEM micrograph of a surface texture of a transparent-conductive-film laminate obtained by depositing a zinc-oxide-based transparent conductive film at a sputtering gas pressure of more than 2.0 Pa.

FIG. 2 is a cross-sectional view illustrating a configuration example of a thin-film solar cell using an amorphous silicon thin film as a photoelectric conversion unit.

FIG. 3 is a cross-sectional view illustrating a configuration example of a hybrid thin-film solar cell in which an amorphous silicon thin film and a crystalline silicon thin film are laminated to form a photoelectric conversion unit.

### DETAILED DESCRIPTION OF THE INVENTION

Hereinafter, an embodiment of the present invention (hereinafter, referred to as “the present embodiment”) will be described in detail in the following order with reference to the drawings.

1. Transparent-conductive-film laminate
1-1. Indium-oxide-based transparent conductive film (I)
1-2. Zinc-oxide-based transparent conductive film (II)
1-3. Characteristics of transparent-conductive-film laminate

2. Manufacturing method for transparent-conductive-film laminate
2-1. First deposition step: deposition of indium-oxide-based transparent conductive film (I)
2-2. Second deposition step: deposition of zinc-oxide-based transparent conductive film (II)

3. Thin-film solar cell and Manufacturing method therefor

<1. Transparent-Conductive-Film Laminate>

A transparent-conductive-film laminate according to the present embodiment has a laminated structure in which an indium-oxide-based transparent conductive film (I) is formed as a ground on a translucent substrate, and a zinc-oxide-based transparent conductive film (II) having excellent roughness characteristics is formed in that order on the indium-oxide-based transparent conductive film (I). Particularly, in this transparent-conductive-film laminate, the indium-oxide-based transparent conductive film (I) to serve as a ground is formed with controlled crystallinity and a controlled surface state.

Specifically, this transparent-conductive-film laminate has a laminated structure in which, on a translucent substrate, an indium-oxide-based transparent conductive film (I) having a surface roughness (Ra) of not more than 1.0 nm is formed as a ground, and a zinc-oxide-based transparent conductive film (II) is formed on the indium-oxide-based transparent conductive film (I). Further, this transparent-conductive-film laminate has, as a laminate, a surface roughness (Ra) of not less than 30 nm, a haze ratio of not less than 8%, and a resistance value of not more than 30 Ω/sq., and has an average absorptivity with respect to light in a wavelength range of 400 nm to 1200 nm of not more than 15%.

Such transparent-conductive-film laminate can achieve a low absorptivity with respect to light and secure a sufficient amount of light to be transmitted to a power generation layer, and also prevent the occurrence of a trouble, particularly to prevent the laminate from being cut together with the silicon power generation layer at the time of laser-cutting the power generation layer. Furthermore, this transparent-conductive-film laminate has a high haze ratio and is excellent in what is called optical confinement, and also has a considerably low resistance. Hence, the transparent-conductive-film laminate is very useful as a surface electrode material for thin-film solar cells.

Furthermore, the laminated structure of the transparent-conductive-film laminate allows the deposition thereof by a low-gas-pressure sputtering method excellent for mass production, and can be formed using DC magnetron sputtering. Therefore, compared to a transparent conductive film which is obtained by a conventional thermal CVD method or a method which is disadvantageous in mass production, such as a method using high gas pressure or RF magnetron sputtering, the transparent-conductive-film laminate according to the present embodiment can be manufactured at low costs. Hence, the use of the transparent-conductive-film laminate according to the present embodiment as a surface electrode material for thin-film solar cells enables a high-efficiency silicon-based thin-film solar cell to be provided inexpensively with a simple process, and hence, is industrially very useful.

<1-1. Indium-Oxide-Based Transparent Conductive Film (I)>

The indium-oxide-based transparent conductive film (I) is characterized in that the indium-oxide-based transparent conductive film (I) with a surface roughness (Ra) of not more than 1.0 nm is formed on a translucent substrate. Furthermore, the maximum difference in height (Rmax) in the surface of the indium-oxide-based transparent conductive film (I) is preferably not more than 50 nm. Furthermore, not more than 100 projections each having a diameter not more than 100 nm may be present per 5 μm square in the surface.

The size of crystal particles of the zinc-oxide-based transparent conductive film (II) formed on the indium-oxide-based transparent conductive film (I) serving as a ground is inversely proportional to the concentration degree of the projections of this ground. Hence, in the case where projections having a size and a concentration degree which exceed the foregoing range of surface roughness (Ra) are present in the indium-oxide-based transparent conductive film (I) due to generation of microcrystals of the transparent conductive film (I), the size of crystal particles of the zinc-oxide-based transparent conductive film (II) deposited on the indium-oxide-based transparent conductive film (I) is smaller, and as a result, a transparent conductive film having a sufficient roughness structure and a sufficient haze ratio cannot be formed.

Indium oxide, having high conductivity and high transparency, is used as a material for the indium-oxide-based transparent conductive film (I). Particularly, a film that contains an additive element, such as Ti, Ga, Mo, Sn, W, and Ce, in the indium oxide can achieve more excellent conductivity, and thus is useful. Among them, a film that is formed by adding Ti, or Ti and Sn to indium oxide has high mobility and low resistance without an increase in carrier concentration, and therefore, a low resistance film having high transmittance in the visible region to the near-infrared region can be achieved. Thus, as the indium-oxide-based transparent conductive film (I), an ITiO film that contains Ti as a dopant, and furthermore, an ITiTO film that contains Ti and Sn as dopants can be preferably used.

The film thickness of the indium-oxide-based transparent conductive film (I) is not particularly limited and depends on material composition and the like, but, is preferably not less than 10 nm and not more than 300 nm, more preferably not less than 30 nm and not more than 100 nm. A film thickness of less than 10 nm causes a decrease in conductivity and difficulties in the control of microcrystal particles suitable for forming projections and depressions in the zinc-oxide-based transparent conductive film (II). On the other hand, a film thickness of more than 300 nm accelerates microcrystallization and the resulting formation of projections in the surface of the film, and, on the contrary, too many nuclei are formed in a unit area, whereby adjacent crystals of the zinc-oxide-based transparent conductive film (II) inhibit the particle growth each other, in other words, the roughness characteristics are reduced, and consequently, there is a risk that the zinc-oxide-based transparent conductive film (II) cannot be used for the present process.

<1-2. Zinc-Oxide-Based Transparent Conductive Film (II)>

As mentioned above, the zinc-oxide-based transparent conductive film (II) is formed on the indium-oxide-based transparent conductive film (I) serving as a ground film and having controlled crystallinity and a controlled surface state. Such formation on the indium-oxide-based transparent conductive film (I) whose crystallinity and surface state are controlled as mentioned above allows a structure being closely packed and having roughness characteristics to be achieved without inhibition of particle growth by adjacent crystals at the time of deposition of the zinc-oxide-based transparent conductive film (II), whereby light scattering and light absorption due to void portions formed between the particles can be controlled. Thus, a film excellent as a surface electrode for thin-film solar cells can be obtained. Furthermore, since the indium-oxide-based transparent conductive film (I) serving as a ground can be prevented from being exposed, the resistance to hydrogen plasma can be improved. Hence, the transparent-conductive-film laminate including the zinc-oxide-based transparent conductive film (II) is useful as a surface electrode for thin-film solar cells.

The zinc-oxide-based transparent conductive film (II) may contain an additive metal element as long as zinc oxide is contained therein as a main component (not less than 90% by weight). Particularly, from the viewpoint of preventing an abnormal discharge under high DC power supply as mentioned later, at least one kind of element selected from Al, Ga, B, Mg, Si, Ti, Ge, Zr, and Hf is preferably added as an additive element that contributes to the conductivity of an oxide film.

The zinc-oxide-based transparent conductive film (II) preferably contains zinc oxide as a main component and contains at least one kind of additive metal element selected from Al and Ga at an atomic number ratio (Al+Ga)/(Zn+Al+Ga) of 0.3 to 6.5 atom % and at an atomic number ratio Al/(Al+Ga) of 30 to 70 atom %. Here, in the case where the total amount of Al and Ga contained in the zinc-oxide-based transparent conductive film (II) exceeds 6.5 atom %, an increase in carrier concentration causes the transmittance in the near-infrared region (a wavelength region of 800 nm to 1200 nm) to be reduced to less than 80%, and thus there is a risk that sufficient transmittance for application to a solar cell cannot be obtained. In this case, a decrease in crystallinity due to an excessive amount of impurities causes difficulties in manufacturing a transparent conductive film with a high surface roughness and a high haze ratio by a sputtering method at high speed. On the other hand, in the case where the total amount of Al and Ga contained in the zinc-oxide-based transparent conductive film (II) is less than 0.3 atom %, a transparent conductive film having sufficient transmittance for application to a solar cell cannot be obtained. Furthermore, in the case where the atomic number ratio of Al and Ga, denoted as Al/(Al+Ga), is less than 30% or more than 70%, particles and arc discharges are likely to be generated at the time of deposition, as mentioned later.

It should be noted that, beside Zn, Al, Ga, and O, the zinc-oxide-based transparent conductive film (II) may contain other elements (for example, In, W, Mo, Ru, Re, Ce, and F) within the range of not impairing the object of the present invention.

The film thickness of the zinc-oxide-based transparent conductive film (II) is not particularly limited and depends on material composition and the like, and is preferably not less than 200 nm and not more than 1000 nm, more preferably not less than 400 nm and not more than 700 nm. A film thickness of less than 200 nm causes difficulties in obtaining a sufficient surface roughness (Ra) and a sufficient haze ratio, on the other hand, a film thickness of more than 1000 nm causes an increase in optical absorptivity, and consequently causes not only lower transmittance, but also lower productivity.

<1-3. Characteristics of Transparent-Conductive-Film Laminate>

The transparent-conductive-film laminate according to the present embodiment has a laminated structure in which the foregoing indium-oxide-based transparent conductive film (I) (a ground film) is formed on a translucent substrate and the foregoing zinc-oxide-based transparent conductive film (II) is laminated on the ground film.

The transparent-conductive-film laminate according to the present embodiment has a surface roughness (Ra) of not less than 30.0 nm. A surface roughness (Ra) of less than 30.0 nm causes a lower haze ratio, whereby when a silicon-based thin-film solar cell is produced, a poor effect of optical confinement is caused, and high conversion efficiency cannot be achieved. Therefore, a surface roughness (Ra) of not less than 30.0 nm allows a sufficient effect of optical confinement to be exerted and high conversion efficiency to be achieved.

However, in the case where the zinc-oxide-based transparent conductive film (II) has a surface roughness (Ra) of more than 80 nm, when a silicon-based thin-film solar cell is produced, the growth of the silicon-based thin film formed on the zinc-oxide-based transparent conductive film (II) is affected, and a gap is produced in an interface between the zinc-oxide-based transparent conductive film (II) and the silicon-based thin film, thereby causing poor contact, and consequently, solar cell characteristics are sometimes reduced. Therefore, in the case of laminating a silicon-based thin film, attention is preferably paid to lamination conditions.

In addition, the transparent-conductive-film laminate according to the present embodiment has a surface resistance value (a resistance value) of not more than 30 Ω/sq. In the case where the transparent-conductive-film laminate is used for a surface electrode of a solar cell, a resistance value of more than 30 Ω/sq. causes a larger loss of electric power in a surface electrode, whereby a high efficiency solar cell cannot be achieved. This transparent-conductive-film laminate has the foregoing laminated structure that includes the indium-oxide-based transparent conductive film (I) and the zinc-oxide-based transparent conductive film (II), and therefore, the transparent-conductive-film laminate is enabled to have a resistance value of not more than 30 Ω/sq. It should be noted that the resistance value of this transparent-conductive-film laminate is preferably not more than 20 Ω/sq., more preferably not more than 13 Ω/sq., still more preferably not more than 10 Ω/sq., most preferably not more than 8 Ω/sq.

Furthermore, the transparent-conductive-film laminate according to the present embodiment has a haze ratio of not less than 8%. The haze ratio is preferably not less than 12%, more preferably not less than 16%, most preferably not less than 20%. Here, the haze ratio of not less than 12% is essential to achieve a conversion efficiency of not less than 10% in a standard silicon-based thin-film solar cell having a single structure. Furthermore, to achieve a conversion efficiency of not less than 12% in the same evaluation as above, the use of a surface electrode having a haze ratio of not less than 16% is effective. Furthermore, to achieve a conversion efficiency of not less than 15% in the same evaluation as above, the use of a surface electrode having a haze ratio of not less than 20% is effective. In a high-efficiency tandem-type silicon-based thin-film solar cell, a surface electrode having a haze ratio of not less than 20% is particularly useful. In the transparent-conductive-film laminate according to the present embodiment, the indium-oxide-based transparent conductive film (I) having controlled crystallinity as a ground film is interposed, and, in addition, the zinc-oxide-based transparent conductive film (II) is laminated on the ground film, whereby a high haze ratio can be achieved.

The inventors' experiences show that, to achieve both of the foregoing characteristics of the haze ratio and the resistance value in the high speed deposition only by the zinc-oxide-based transparent conductive film, the film thickness of the zinc-oxide-based transparent conductive film needs to be not less than 1500 nm. However, with such film thickness, mass productivity is considerably decreased, which is not preferable.

Furthermore, the transparent-conductive-film laminate according to the present embodiment has an average absorptivity with respect to light in a wavelength range of 400 nm to 1200 nm of not more than 15%. Such optical absorptivity in a wavelength range of 400 nm to 1200 nm of not more than 15% leads to a lower loss of optical absorption, whereby the transparent-conductive-film laminate can be preferably used as a surface electrode for solar cells.

<2. Manufacturing Method for Transparent-Conductive-Film Laminate>

Next, a manufacturing method for a transparent-conductive-film laminate according to the present embodiment will be described. The manufacturing method for a transparent-conductive-film laminate according to the present embodiment includes: a first deposition step of depositing an indium-oxide-based transparent conductive film (I) on a translucent substrate by a sputtering method, the indium-oxide-based transparent conductive film (I) having a surface roughness (Ra) of not more than 1 nm, and preferably having a maximum difference in height (Rmax) in the surface of not more than 50 nm, or having not more than 100 projections having a diameter of not more than 100 nm that are present per 5 μm square in the surface; and a second deposition step of depositing a zinc-oxide-based transparent conductive film (II) on the indium-oxide-based transparent conductive film (I) by a sputtering method. Hereinafter, the deposition step and the deposition condition for each of the transparent conductive film will be described in more detail.

<2-1. First Deposition Step: Deposition of Indium-Oxide-Based Transparent Conductive Film (I)>

In the first deposition step, a indium-oxide-based transparent conductive film (I) having a surface roughness (Ra) of not more than 1 nm, and preferably having a maximum difference in height (Rmax) in the surface of not more than 50 nm, or having not more than 100 projections having a diameter of not more than 100 nm that are present per 5 μm square in the surface is formed on a translucent substrate by a sputtering method so as to have a film thickness of not less than 10 nm and not more than 300 nm.

More specifically, the deposition is performed using a sputtering method such as a magnetron sputtering method under conditions of a substrate temperature of not more than 50° C. and a sputtering gas pressure of not less than 0.1 Pa and not more than 2.0 Pa. This allows the formation of the indium-oxide-based transparent conductive film (I) as an amorphous film in which the formation of microcrystals is inhibited.

At the time of the deposition using a sputtering method, the kind of sputtering gas to be used is not particularly limited, but, argon gas is basically preferably used. However, to make the indium-oxide-based transparent conductive film (I) amorphous, steam (H₂O gas) or hydrogen (H₂) gas may be mixed in. The introduction of H₂O gas or H₂ gas allows the surface roughness (Ra) and the haze ratio of a laminate to be formed to be more excellent. It should be noted that, from the viewpoint of the resistance value of the laminate, the partial pressure of H₂O gas and the partial pressure of H₂ gas are preferably controlled, specifically, the partial pressure of H₂O gas is preferably controlled to not more than 0.05 Pa, and the partial pressure of H₂ gas is preferably controlled to not more than 0.03 Pa.

In addition, in the deposition of the indium-oxide-based transparent conductive film (I), there can be used an oxide sintered compact target that contains indium oxide as a main component and contains at least one kind of metal element selected from Ti, Ga, Mo, Sn, W, and Ce. It should be noted that, when an oxide film is obtained using an oxide sintered compact target by a sputtering method, the composition of the oxide film is equal to that of the target unless a volatile substance is contained.

In the present embodiment, it is preferable that the amorphous film is formed without heating a substrate, and then, immediately after the application of heat treatment, the zinc-oxide-based transparent conductive film (II) is formed. This enables the crystal particle boundary area of the zinc-oxide-based transparent conductive film (II) to be controlled; large crystal particles to be obtained without mutual inhibition of the growth by adjacent crystal particles; and a film having a higher surface roughness (Ra) and a higher haze ratio can be efficiently deposited. Furthermore, since the particle growth is accelerated, the film is closely packed, whereby a film with low absorptivity can be effectively deposited.

<2-2. Second Deposition Step: Deposition of Zinc-Oxide-Based Transparent Conductive Film (II)>

In the second deposition step, on the indium-oxide-based transparent conductive film (I) deposited in the first deposition step, a zinc-oxide-based transparent conductive film (II) is deposited by a sputtering method so as to have a film thickness of not less than 200 nm and not more than 1000 nm.

More specifically, the deposition is performed using a sputtering method, such as a magnetron sputtering method, under conditions of a substrate temperature of not less than 200° C. and not more than 450° C. and a sputtering gas pressure of not less than 0.1 Pa and not more than 2.0 Pa. This allows the formation of the zinc-oxide-based transparent conductive film (II) which is a crystalline film being closely packed, having a low optical absorption loss, and having excellent roughness characteristics.

In the deposition by a sputtering method, an oxide sintered compact target may contain at least one kind of metal element selected from Al, Ga, B, Mg, Si, Ti, Ge, Zr, and Hf as long as the oxide sintered compact target contains zinc oxide as a main component (not less than 90% by weight).

In addition, from the viewpoint of preventing an abnormal discharge under high DC power supply, particularly, an oxide sintered compact target that contains at least one kind of metal element selected from Al and Ga as an additive element to contribute to the conductivity of an oxide film is preferably used. Specifically, as mentioned above, there is preferably used an oxide sintered compact target that allows the deposition of an oxide film containing at least one kind of metal element selected from Al and Ga at an atomic number ratio (Al+Ga)/(Zn+Al+Ga) of 0.3 to 6.5 atom % and at an atomic number ratio Al/(Al+Ga) of 30 to 70 atom %.

In the case where the total amount of Al and Ga contained in the deposited zinc-oxide-based transparent conductive film (II) exceeds the foregoing range, there is a risk that a film having sufficient characteristics for the application to solar cells cannot be obtained. In addition, in the case where Al and Ga are contained at an atomic number ratio, denoted as Al/(Al+Ga), of more than 70%, due to a spinel-type oxide phase rich in Al that is present in the sintered compact, an arc discharge is likely to occur at the time of direct-current sputtering performed by increasing direct-current power supply, which is not preferable. On the other hand, in the case where Al and Ga are contained at the foregoing atomic number ratio of less than 30%, due to a spinel-type oxide phase rich in Ga that is present in the sintered compact, particles are likely to be generated at the time of performing long-time continuous sputtering, whereby an arc discharge is induced, which is not preferable. The foregoing Patent document 4 describes the details.

It should be noted that, as is the case with the deposition of the indium-oxide-based transparent conductive film, when an oxide film is obtained using a target by a sputtering method, the composition of the oxide film is equal to that of the target unless a volatile substance is contained.

As mentioned above, as a deposition condition in the second deposition step, a sputtering gas pressure of not less than 0.1 Pa and not more than 2.0 Pa is applied. In the present embodiment, the crystallinity and the surface state of the indium-oxide-based transparent conductive film (I) deposited in the first deposition step are controlled so that the indium-oxide-based transparent conductive film (I) has a surface roughness (Ra) of not more than 1.0 nm, and therefore, the zinc-oxide-based transparent conductive film (II) is enabled to be deposited at such low gas pressure.

Here, in the case where the sputtering gas pressure is less than 0.1 Pa, a film having a high surface-roughness is hard to be obtained, that is, a film with an Ra value of not less than 30.0 nm cannot be achieved. On the other hand, in the case where the sputtering gas pressure is more than 2.0 Pa, a resultant film has a lower density, thereby causing an increase in absorptivity and a decrease in carrier mobility, whereby optical characteristics and conductivity are impaired. Furthermore, a film with such low density causes a higher loss of optical absorption, and therefore, in the case where such film is used as a surface electrode of a thin-film solar cell, the cell efficiency is considerably reduced, which is not preferable.

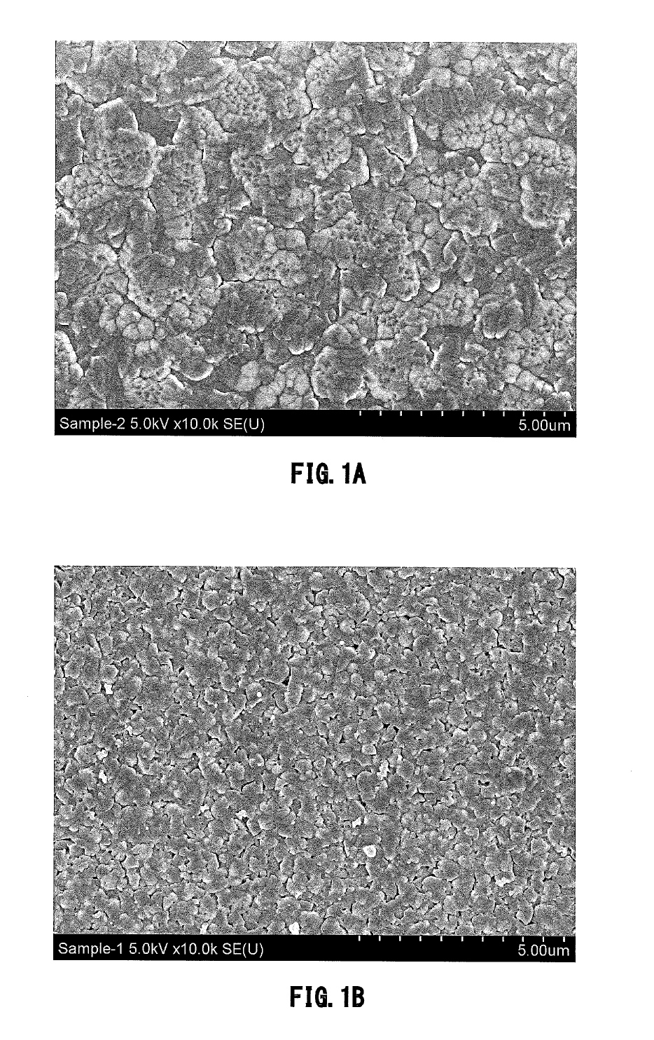

FIG. 1 (A) is a SEM image of a surface texture of a transparent-conductive-film laminate obtained by depositing a zinc-oxide-based transparent conductive film (II) at a sputtering gas pressure of not less than 0.1 Pa and not more than 2.0 Pa, and FIG. 1 (B) is a SEM image of a surface texture of a transparent-conductive-film laminate obtained by depositing a zinc-oxide-based transparent conductive film (II) at a sputtering gas pressure of more than 2.0 Pa. As shown in FIG. 1, it is understood that the deposition at a sputtering gas pressure of more than 2.0 Pa leads to a low film density, on the other hand, the deposition at a low sputtering gas pressure of not more than 2.0 Pa enables a film with high density to be formed.

Furthermore, also from the viewpoint of mass productivity, the deposition at a high gas pressure of more than 2.0 Pa is not preferable. For example, in static facing deposition, in order to achieve a high deposition rate of not less than 50 nm/min by supplying a high electric power with a direct-current power density of not less than 2.76 W/cm² to a target, the sputtering gas pressure needs to be not more than 2.0 Pa. A sputtering gas pressure of more than 2.0 Pa causes an abnormal discharge to occur frequently due to an induction of dust inside a deposition chamber and the like, whereby the film thickness and furthermore the film quality are hard to be controlled, and therefore such gas pressure is not useful.

Furthermore, the condition of substrate temperature at the time of deposition in the second deposition step is not less than 200° C. and not more than 450° C. Such temperature condition allows the crystallinity of the transparent conductive film to be favorable, the mobility of a career electron to be increased, and excellent conductivity to be achieved. It should be noted that a substrate temperature of less than 200° C. leads to the poor growth of particles of the film, whereby a film having a large Ra value cannot be obtained. On the other hand, a substrate temperature of more than 450° C. not only causes problems, such as an increase in electric energy required for heating and the resulting increase in manufacturing costs, but also leads to the c-axis orientation of the deposited zinc-oxide-based transparent conductive film (II) to be higher, and accordingly, a film surface is made flatter and it is hard to achieve a film with roughness having a haze ratio of not less than 8%.

Here, in the deposition of the foregoing transparent conductive film, when power supply to a sputtering target is increased, the deposition rate is increased and the productivity of the film is improved (high speed deposition). However, according to the prior art, it is hard to achieve the foregoing useful characteristics.

It should be noted that the high speed deposition mentioned here means sputtering deposition that is performed by increasing the power supply to a target to not less than 2.76 W/cm², and this allows, for example, a deposition rate of not less than 90 nm/min to be achieved in static facing deposition, and a zinc-oxide-based transparent conductive film having a low optical absorption loss and excellent surface roughness characteristics to be obtained. Furthermore, also passage-type deposition (transfer deposition) in which deposition is performed with a substrate passing through above a target, and also high-speed transfer deposition of, for example, 5.1 nm·m/min (when the value is divided by a transfer rate (m/min), a film thickness (nm) to be obtained is calculated) in which deposition is performed at the same input power density allow a zinc-oxide-based transparent conductive film having a low optical absorption loss and excellent surface roughness characteristics to be obtained.

On the other hand, in the present embodiment, for example, even in the case where high speed deposition in which an input power density to a target is increased to not less than 2.76 W/cm² is carried out, the deposition under the foregoing conditions makes it possible to efficiently manufacture a transparent-conductive-film laminate having an average optical absorptivity in a wavelength range of 400 nm to 1200 nm of not more than 15% and having surface roughness characteristics that achieve a surface roughness (Ra) of not less than 30.0 nm and a haze ratio of not less than 8.0%. Particularly, the foregoing surface roughness (Ra) and surface resistance can be achieved even in a thin film having a film thickness of not more than 500 nm, and such smaller film thickness allows transmittance to be improved. It should be noted that deposition rate is not particularly limited.

As mentioned above, the manufacturing method for a transparent-conductive-film laminate according to the present embodiment enables a transparent-conductive-film laminate to be manufactured only by a sputtering method, and therefore, the resulting transparent-conductive-film laminate is not only excellent in conductivity and the like as a transparent-conductive-film for transparent surface electrodes of thin-film solar cells, but also leads to an effective reduction in costs, compared with a transparent conductive film obtained by a conventional thermal CVD method, RF sputtering, or DC sputtering at high gas pressure and with hydrogen introduction. Hence, a high efficiency silicon-based thin-film solar cell can be provided inexpensively with a simple process, and thus such manufacturing method for a transparent-conductive-film laminate is industrially very useful.

Furthermore, the thus-manufactured transparent-conductive-film laminate has a lower loss of optical absorption in a wavelength range of 400 nm to 1200 nm and has a high haze ratio and excellent conductivity. Hence, this transparent-conductive-film laminate allows a larger amount of light to be transmitted to a power generation layer and sunlight energy to be considerably effectively converted into electric energy, and thus is very useful as a surface electrode for high efficiency solar cells.

<3. Thin-Film Solar Cell and Manufacturing Method Therefor>

A thin-film solar cell according to the present embodiment includes a translucent substrate, a transparent-conductive-film laminate, a photoelectric conversion layer unit, and a back surface electrode layer, in which, on the translucent substrate, the transparent-conductive-film laminate, the photoelectric conversion layer unit, and the back surface electrode layer are formed in that order.

Furthermore, the thin-film solar cell according to the present embodiment is a photoelectric conversion element characterized in that the foregoing transparent-conductive-film laminate is used as an electrode. In other words, the thin-film solar cell uses a transparent-conductive-film laminate as an electrode, in which the transparent-conductive-film laminate has a structure, the structure including an indium-oxide-based transparent conductive film (I) with a surface roughness (Ra) of not more than 1.0 nm formed on a translucent substrate, and a zinc-oxide-based transparent conductive film (II) formed on the indium-oxide-based transparent conductive film (I); and has, as a laminate, a surface roughness (Ra) of not less than 30 nm, a haze ratio of not less than 8%, and a resistance value of not more than 30 Ω/sq., and has an average absorptivity with respect to light in a wavelength range of 400 nm to 1200 nm of not more than 15%. It should be noted that the structure of the solar cell element is not particularly limited, and examples of the structure include a PN junction type in which a p-type semiconductor and an n-type semiconductor are laminated, and a PIN junction type in which an insulating layer (I layer) is interposed between a p-type semiconductor and an n-type semiconductor.

Generally, depending on the types of semiconductors, thin-film solar cells are roughly classified into: silicon-based solar cells that use a silicon-based semiconductor thin film, such as microcrystal silicon and/or amorphous silicon, as a photoelectric conversion element; compound thin-film-based solar cells that use a thin film of a compound semiconductor as a photoelectric conversion element, the thin film of the compound semiconductor being typified by CuInSe-based, Cu(In,Ga)Se-based, Ag(In,Ga)Se-based, CuInS-based, Cu(In,Ga)S-based, Ag(In,Ga)S-based thin films, solid solutions of these, GaAs-based, and CdTe-based thin films; and dye-sensitized solar cells (also called Gratzel solar cell) that use organic dye. The thin-film solar cell according to the present embodiment is included in any of the foregoing type cells, and the use of the foregoing transparent-conductive-film laminate as an electrode leads to high conversion efficiency to be achieved. Particularly, in the silicon-based solar cells and compound thin film solar cells, a transparent conductive film is indispensable for an electrode on the side of incidence of sunlight (the light receiving unit side, the front side), and the use of the transparent-conductive-film laminate according to the present embodiment allows a high conversion efficiency property to be achieved.

A p-type or n-type conductive semiconductor layer in a photoelectric conversion unit plays a role in producing an internal electric field inside the photoelectric conversion unit. The value of open-circuit voltage (Voc), one of the important characteristics of thin-film solar cells, is dependent on the intensity of this internal electric field. Furthermore, an i-type layer is substantially an intrinsic semiconductor layer and occupies most of the thickness of a photoelectric conversion unit. Photoelectric conversion action occurs mainly in this i-type layer.

Therefore, an i-type layer is commonly called an i-type photoelectric conversion layer or just a photoelectric conversion layer. A photoelectric conversion layer is not limited to an intrinsic semiconductor layer, but may be a layer slightly doped with a p-type or n-type to the extent that a loss of light absorbed by doped impurities (dopant) causes no problem.

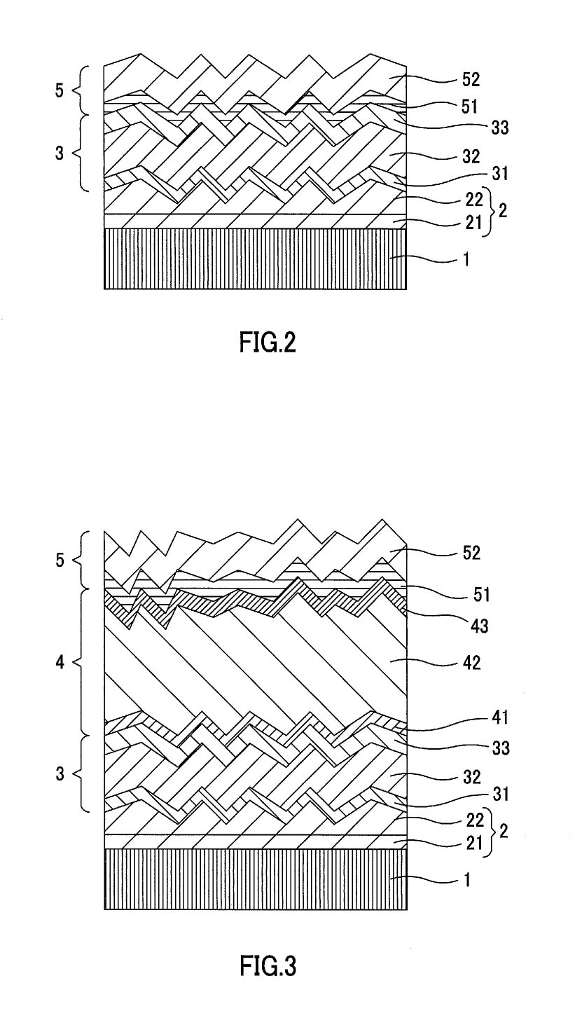

Here, FIG. 2 illustrates an example of the structure of a silicon-based amorphous thin-film solar cell. As a silicon-based thin-film solar cell that uses a silicon-based thin film as a photoelectric conversion unit (an optical absorption layer), besides amorphous thin-film solar cells, microcrystalline thin-film solar cells and crystalline thin-film solar cells, and hybrid thin-film solar cells obtained by laminating a microcrystalline thin-film solar cell and a crystalline thin film solar cell have been put in practical use. It should be noted that, as mentioned above, a photoelectric conversion unit or a thin-film solar cell in which a photoelectric conversion layer occupying a main part of the unit or the solar cell is amorphous is called an amorphous unit or an amorphous thin-film solar cell. On the other hand, a photoelectric conversion unit or a thin-film solar cell in which the photoelectric conversion layer is crystalline is called a crystalline unit or a crystalline thin-film solar cell. Furthermore, a photoelectric conversion unit or a thin-film solar cell in which the photoelectric conversion layer is microcrystalline is called a microcrystalline unit or a microcrystalline thin-film solar cell.

To further improve the conversion efficiency of such thin-film solar cell, there is a method in which two or more photoelectric conversion units are laminated to form a tandem-type solar cell. For example, in this method, a front unit including a photoelectric conversion layer having a large band gap is disposed on the light incidence side of a thin-film solar cell, and, at the back thereof, a back unit including a photoelectric conversion layer having a small band gap is disposed. Such method allows photoelectric conversion over the wide wavelength range of incident light and improvement in the conversion efficiency as the whole of a solar cell. Among the tandem solar cells, a tandem solar cell formed by laminating an amorphous photoelectric conversion unit and a crystalline or microcrystalline photoelectric conversion unit is particularly called a hybrid thin-film solar cell.

FIG. 3 illustrates an example of the structure of a hybrid thin-film solar cell. In a hybrid thin-film solar cell, for example, i-type amorphous silicon can photoelectrically convert the light having a wavelength up to approximately 800 nm on the long wavelength side, while i-type crystalline or microcrystalline silicon can photoelectrically convert the light having a longer wavelength up to approximately 1150 nm.

Next, with reference to FIGS. 2 and 3, the configuration of the thin-film solar cell according to the present embodiment will be more specifically described. As illustrated in FIGS. 2 and 3, the thin-film solar cell according to the present embodiment is configured such that a transparent-conductive-film laminate 2 including a transparent conductive film 21 that serves as the foregoing indium-oxide-based transparent conductive film (I) and a transparent conductive film 22 that serves as the zinc-oxide-based transparent conductive film (II) is formed on the translucent substrate 1.

As the translucent substrate 1, a plate-like member or a sheet-like member, made of glass, transparent resin, or the like, is used. An amorphous photoelectric conversion unit 3 is formed on the transparent-conductive-film laminate 2. The amorphous photoelectric conversion unit 3 includes a p-type amorphous silicon carbide layer 31, an i-type non-doped amorphous silicon photoelectric conversion layer 32, and an n-type silicon-based interface layer 33. To prevent the transmittance of the transparent-conductive-film laminate 2 from being decreased by the reduction thereof, the p-type amorphous silicon carbide layer 31 is formed at a substrate temperature of not more than 180° C.

In a hybrid thin-film solar cell illustrated in FIG. 3, a crystalline photoelectric conversion unit 4 is formed on the amorphous photoelectric conversion unit 3. The crystalline photoelectric conversion unit 4 includes a p-type crystalline silicon layer 41, an i-type crystalline silicon photoelectric conversion layer 42, and an n-type crystalline silicon layer 43. A high frequency plasma CVD method is suitable for the formation of the amorphous photoelectric conversion unit 3 and the crystalline photoelectric conversion unit 4 (hereinafter, both of the units are collectively called just a “photoelectric conversion unit”). The conditions to be preferably used for the formation of the photoelectric conversion unit are a substrate temperature of not less than 100° C. and not more than 250° C. (however, for the p-type amorphous silicon carbide layer 31, not more than 180° C.), a pressure of not less than 30 Pa and not more than 1500 Pa, and a high frequency power density of not less than 0.01 W/cm² and not more than 0.5 W/cm². As a source gas to be used for the formation of the photoelectric conversion unit, silicon-containing gas, such as SiH₄ or Si₂H₆, or gas obtained by mixing the foregoing gas with H₂ is used. As a dopant gas to foul′ a p-type or n-type layer in the photoelectric conversion unit, B₂H₆, PH₃, or the like is preferably used.

A back surface electrode 5 is formed on the n-type silicon-based interface layer 33 illustrated in FIG. 2 or on the n-type silicon-based interface layer 43 illustrated in FIG. 3. The back surface electrode 5 includes a transparent reflective layer 51 and a back surface reflective layer 52. For the transparent reflective layer 51, metal oxide, such as ZnO or ITO, is preferably used. For the back surface reflective layer 52, Ag, Al, or an alloy of these is preferably used.

To form the back surface electrode 5, a sputtering method, a vapor deposition method, or the like is preferably used. The back surface electrode 5 usually has a thickness of not less than 0.5 μm and not more than 5 μm, preferably not less than 1 μm and not more than 3 μm. After the formation of the back surface electrode 5, heating is applied at the ambient temperature not less than the formation temperature of the p-type amorphous silicon carbide layer 31 under near atmospheric pressure, whereby a solar cell is completed. As a gas used for the heating atmosphere, the atmosphere, nitrogen, a mixture of nitrogen and oxygen, or the like is preferably used. In addition, the “near atmospheric pressure” represents a range of approximately not less than 0.5 atmospheric pressure and not more than 1.5 atmospheric pressure.

As described above, the thin-film solar cell according to the present embodiment provides a silicon-based thin-film solar cell that uses the foregoing transparent-conductive-film laminate 2 as an electrode. The transparent-conductive-film laminate 2 has a laminated structure in which an indium-oxide-based transparent conductive film (I) having controlled crystallinity and a controlled surface state is formed as a ground on a translucent substrate and a zinc-oxide-based transparent conductive film (II) having excellent roughness characteristics is formed in that order on the indium-oxide-based transparent conductive film (I), whereby a transparent conductive film with lower resistance for surface transparent electrodes of thin-film solar cells is achieved. Furthermore, compared with a transparent conductive film obtained by a conventional thermal CVD method, RF sputtering, or DC sputtering at high gas pressure and with hydrogen introduction, the transparent-conductive-film laminate 2 can be more inexpensively formed and allows a high efficiency silicon-based thin-film solar cell to be manufactured more simply at lower costs, and thus is industrially very useful.

It should be noted that, in the structure of a hybrid thin-film solar cell illustrated in FIG. 3, the number of the photoelectric conversion units is not necessarily two, and the hybrid thin-film solar cell may have an amorphous or crystalline single structure or a laminated structure having three or more layers.

### EXAMPLES

Hereinafter, the transparent conductive film with a double-layer laminated structure according to the present invention will be described by comparing Examples with Comparative Examples. It should be noted that the present invention is not limited to these Examples.

<Evaluation Method>

(1) A target used for preparing a transparent conductive film was quantitatively analyzed by an ICP emission spectrophotometer (SPS4000 manufactured by Seiko Instruments Inc.).

(2) The surface roughness (Ra) of a film and the number of projections in a region of 5 μm×5 μm of a transparent conductive film (I) were measured using an atomic force microscope (NS-III, D5000 system, manufactured by Digital Instruments Co., Ltd.).

(3) Film-thickness was measured in the following procedure. That is, an oil-based marking ink was applied beforehand to a part of a substrate before deposition, then, after the deposition, the oil-based marking ink was removed by ethanol to form a non-coated portion, and the difference in height between the non-coated portion and a coated portion was measured and determined using a contact type surface profiler (Alpha-Step IQ, manufactured by KLA-Tencor Corporation).

(4) The optical absorptivity of a transparent-conductive-film laminate was calculated from the transmittance and reflectance profiles of a substrate and a substrate with a transparent-conductive-film laminate that were measured using a spectrophotometer (U-4000, manufactured by Hitachi, Ltd.).

(5) Based on JIS K7136, the haze ratio of a film was evaluated using a haze meter (HM-150, manufactured by MURAKAMI COLOR RESEARCH LABORATORY CO., LTD.).

(6) The resistance value of a transparent conductive thin film was measured by a four-probe method using a resistivity meter, Loresta EP (MCP-T360, manufactured by DIA Instruments, Co., Ltd.).

### Example 1

Using the following procedure, an indium-oxide-based transparent conductive film (I) containing titanium (Ti) and a zinc-oxide-based transparent conductive film (II) were laminated in that order on a translucent substrate to prepare a transparent-conductive-film laminate with a high surface-roughness.

(Preparation of Indium-Oxide-Based Transparent Conductive Film (I))

First, under the conditions listed in the following Table 1, an indium-oxide-based transparent conductive film (I) to serve as a ground was deposited. The composition of a target (manufactured by Sumitomo Metal Mining Co., Ltd.) used for preparation of the indium-oxide-based transparent conductive film (I) was quantitatively analyzed using the foregoing method (1), and, as a result, it was found that the target had an atomic number ratio Ti/(In+Ti) of 0.50 atom %. Furthermore, the target had a purity of 99.999% and a size of 6 inches in diameter and 5 mm in thickness.

This sputtering target was attached to a cathode for ferromagnetic targets in a direct-current magnetron sputtering apparatus (SPF503K, manufactured by Tokki Corporation) (the horizontal magnetic field strength at a position 1 cm away from the surface of the target was approximately 80 kA/m (1 kG) at the maximum), and a Corning 7059 glass substrate having a thickness of 1.1 mm was attached to a surface opposed to the sputtering target. The distance of the sputtering target and the substrate was 50 mm.

At the time when the degree of vacuum in a chamber reached 2×10⁻⁴ Pa or less, an Ar gas obtained by mixing 1 vol. % of O₂ gas thereinto was introduced into a chamber to obtain a gas pressure of 0.6 Pa, and under a state where the substrate was un-heated (25° C.), a direct-current input power of 300 W ((Input Power Density to Target)=(Direct-Current Input Power)/(Surface Area of Target)=300 W/181 cm²=1.660 W/cm²) was applied between the target and the substrate to generate direct current plasma. Pre-sputtering was performed for 10 minutes to clean the surface of the target, and then, sputtering deposition was performed in a state where the substrate stood still right above the center of the target, whereby an indium-oxide-based transparent conductive film having a film thickness of 100 nm was formed on the substrate.

The surface roughness and the number of projections of the obtained indium-oxide-based transparent conductive film (I) were measured by the foregoing evaluation method (2), and as a result, it was confirmed that the indium-oxide-based transparent conductive film (I) had a surface roughness (Ra) of 0.4 nm, a maximum difference in height (Rmax) of 7.8 nm, and no crystal having a diameter of not less than 100 nm present per 5 μm square. The following Table 2 collectively shows the results.

(Preparation of Zinc-Oxide-Based Transparent Conductive Film (II))

Next, under the conditions listed in the following Table 1, a zinc-oxide-based transparent conductive film (II) having a high surface-roughness was formed on the indium-oxide-based transparent conductive film (I), using a zinc-oxide-based sintered compact target (manufactured by Sumitomo Metal Mining Co., Ltd.) containing aluminum and gallium as additive elements. The composition of the target was an atomic number ratio of Al/(Zn+Al) of 0.30 atom % and an atomic number ratio of Ga/(Zn+Ga) of 0.30 atom %, respectively. Each of the targets had a purity of 99.999% and a size of 6 inches in diameter and 5 mm in thickness.

The deposition of the zinc-oxide-based transparent conductive film (II) was performed in such a manner that a vacuuming was carried out on a chamber, and at the time when the degree of vacuum in the chamber reached 2×10⁻⁴ Pa or less, Ar gas having a purity of 99.9999% by mass was introduced into the chamber to obtain a gas pressure of 1.0 Pa. A direct-current input power of 400 W ((Input Power Density to Target)=(Direct-Current Input Power)/(Surface Area of Target)=400 W/181 cm²=2.210 W/cm²) was applied between the target and the substrate at a substrate temperature of 300° C. to generate direct-current plasma. Pre-sputtering was performed for 10 minutes to clean the surface of the target, and then, sputtering deposition was performed in a state where the substrate stood still right above the center of the target, whereby a zinc-oxide-based transparent conductive film (II) having a film thickness of 600 nm was formed to obtain a transparent-conductive-film laminate.

The film thickness, the optical absorptivity, the surface roughness (Ra), the haze ratio, and the resistance value of the obtained transparent-conductive-film laminate were measured using the foregoing evaluation methods (1) to (6).

As a result, it was confirmed that the transparent-conductive-film laminate had a film thickness of 700 nm, an average optical absorptivity in a wavelength range of 400 nm to 600 nm of 9.9% and an average optical absorptivity in a wavelength range of 400 nm to 1200 nm of 9.2%, a surface roughness (Ra) of 38.2 nm, a haze ratio of 16.2%, and a resistance value of 9.8 Ω/sq. The following Table 2 collectively shows the characteristic evaluation results of the obtained transparent-conductive-film laminate.

From these results, it was confirmed that a transparent-conductive-film laminate having a low optical absorption loss, a high haze ratio, an excellent effect of optical confinement, and a low resistance was obtained at high speed only by a magnetron sputtering method at low gas pressure.

### Example 2

### Comparative Example 1

Transparent-conductive-film laminates were prepared and the characteristics thereof were measured and evaluated in the same manner as in Example 1, except that the substrate temperatures at the time of deposition of the indium-oxide-based transparent conductive films (I) were 50° C. (Example 2) and 100° C. (Comparative Example 1), respectively.

The following Table 2 shows the obtained results. As shown in Table 2, in Comparative Example 1, the indium-oxide-based transparent conductive film (I) had a surface roughness (Ra) of more than 1 nm, namely 3.2 nm, and a maximum difference in height (Rmax) of more than 50 nm, and 650 crystal particles having a diameter of more than 100 nm were present per 5 μm square in the indium-oxide-based transparent conductive film (I), whereby particle growth in the zinc-oxide-based transparent conductive film (II) was inhibited, and as a result, the surface roughness (Ra) and the haze ratio of the transparent-conductive-film laminate were very low, namely 5.2 nm and 2.1%, respectively.

Thus, in Comparative Example 1, a transparent-conductive-film laminate having a low optical absorption loss, a high haze ratio, an excellent effect of optical confinement, and a low resistance was not obtained at high speed only by a magnetron sputtering method at low gas pressure. On the other hand, in Example 2, as is the case with Example 1, a transparent-conductive-film laminate useful as a surface electrode for solar cells was formed.

### Examples 3 and 4

### Comparative Examples 2 and 3

Transparent-conductive-film laminates were prepared and the characteristics thereof were measured and evaluated in the same manner as in Example 1, except that the indium-oxide-based transparent conductive films (I) had a film thickness of 0 nm (no film) (Comparative Example 2), 10 nm (Example 3), 250 nm (Example 4), and 350 nm (Comparative Example 3), respectively.

The following Table 2 shows the obtained results. As shown in Table 2, in Comparative Example 2, an indium-oxide-based transparent conductive film (I) was not provided, whereby not only the surface roughness (Ra) and the haze ratio of the transparent-conductive-film laminate were very low, namely 5.0 nm and 1.8%, respectively, but also, the resistance value thereof was high, namely 36.3 Ω/sq. Furthermore, in Comparative Example 3, the thickness of the indium-oxide-based transparent conductive film (I) was too thick, namely 350 nm, whereby generation of microcrystals was promoted, and the indium-oxide-based transparent conductive film (I) had a surface roughness (Ra) of more than 1 nm, namely 1.2 nm, and a maximum difference in height (Rmax) of more than 50 nm, namely 54.4 nm, and 112 crystal particles having a diameter of more than 100 nm were present per 5 um square in the indium-oxide-based transparent conductive film (I), whereby particle growth in the zinc-oxide-based transparent conductive film (II) was inhibited, and as a result, the surface roughness (Ra) and the haze ratio of the transparent-conductive-film laminate were low, namely 28.2 nm and 6.0%, respectively.

Thus, in Comparative Examples 2 and 3, a transparent-conductive-film laminate having a low optical absorption loss, a high haze ratio, an excellent effect of optical confinement, and a low resistance was not obtained at high speed only by a magnetron sputtering method at low gas pressure. On the other hand, in Examples 3 and 4, as is the case with Example 1, a transparent-conductive-film laminate useful as a surface electrode for solar cells was formed.

### Examples 5 to 7

Transparent-conductive-film laminates were prepared and the characteristics thereof were measured and evaluated in the same manner as in Example 1, except that H₂O gas was introduced at the time of deposition of the indium-oxide-based transparent conductive films (I) at an H₂O partial pressure of 0.007 Pa (Example 5), 0.03 Pa (Example 6), and 0.05 Pa (Example 7), respectively.

The following Table 2 shows the obtained results. As shown in Table 2, compared with Example 1, the introduction of H₂O gas allowed a transparent-conductive-film laminate having a higher surface roughness (Ra), a higher haze ratio, and a more excellent effect of optical confinement, and being more useful as a surface electrode for solar cells to be obtained.

It should be noted that there was observed a tendency for a higher partial pressure of H₂O to lead to a higher resistance value. Hence, it was found that an H₂O partial pressure of not more than 0.05 Pa was preferable.

### Examples 8 to 10

Transparent-conductive-film laminates were prepared and the characteristics thereof were measured and evaluated in the same manner as in Example 1, except that H₂ gas was introduced at the time of deposition of the indium-oxide-based transparent conductive films (I) at an H₂ partial pressure of 0.005 Pa (Example 8), 0.02 Pa (Example 9), and 0.03 Pa (Example 10), respectively.

The following Table 2 shows the obtained results. As shown in Table 2, compared with Example 1, the introduction of H₂ gas allowed a transparent-conductive-film laminate having a higher surface roughness (Ra), a higher haze ratio, and a more excellent effect of optical confinement, and being more useful as a surface electrode for solar cells to be obtained.

It should be noted that there was observed a tendency for a higher partial pressure of H₂ to lead to a higher resistance value. Hence, it was found that an H₂ partial pressure of not more than 0.03 Pa was preferable.

### Examples 11 and 12

### Comparative Example 4

Transparent-conductive-film laminates were prepared and the characteristics thereof were measured and evaluated in the same manner as in Example 1, except that the deposition of the zinc-oxide-based transparent conductive films (II) was performed at a gas pressure of 0.5 Pa (Example 11), 2.0 Pa (Example 12), and 2.5 Pa (Comparative Example 4), respectively.

The following Table 2 shows the obtained results. As shown in Table 2, in Comparative Example 4, the optical absorptivity in a wavelength range of 400 nm to 600 nm and the optical absorptivity in a wavelength range of 400 nm to 1200 nm were higher, thereby causing an increase in optical absorption loss. This is considered because a high gas pressure of 2.5 Pa caused a low film density of the zinc-oxide-based transparent conductive film (II), thereby causing an increase in optical absorption loss.

Thus, in Comparative Example 4, a transparent-conductive-film laminate having a low optical absorption loss, a high haze ratio, an excellent effect of optical confinement, and a low resistance was not obtained at high speed only by a magnetron sputtering method at low gas pressure. On the other hand, in Examples 11 and 12, as is the case with Example 1, a transparent-conductive-film laminate useful as a surface electrode for solar cells was formed.

### Examples 13 and 14

### Comparative Examples 5 and 6

Transparent-conductive-film laminates were prepared and the characteristics thereof were measured and evaluated in the same manner as in Example 1, except that the deposition of the zinc-oxide-based transparent conductive films (II) was performed at a substrate temperature of 150° C. (Comparative Example 5), 200° C. (Example 13), 450° C. (Example 14), and 500° C. (Comparative Example 6), respectively.

The following Table 2 shows the obtained results. As shown in Table 2, in Comparative Example 5, the heating temperature at the time of forming the zinc-oxide-based transparent conductive film (II) was insufficient, namely 150 C.°, whereby particle growth was not promoted, and, as a result, the surface roughness (Ra) and the haze ratio of the transparent-conductive-film laminate were low, namely 5.3 nm and 2.3%, respectively. Furthermore, in Comparative Example 6, the heating temperature at the time of forming the zinc-oxide-based transparent conductive film (II) was high, namely 500° C., whereby it is considered that, with crystal growth of c-axis orientation, the film was made more flat, and as a result, the surface roughness (Ra) and the haze ratio of the transparent-conductive-film laminate were low, namely 28.9 nm and 7.6%, respectively.

Thus, in Comparative Examples 5 and 6, a transparent-conductive-film laminate having a low optical absorption loss, a high haze ratio, an excellent effect of optical confinement, and a low resistance was not obtained at high speed only by a magnetron sputtering method at low gas pressure. On the other hand, in Examples 13 and 14, as is the case with Example 1, a transparent-conductive-film laminate useful as a surface electrode for solar cells was formed.

### Examples 15 and 16

### Comparative Examples 7 and 8

Transparent-conductive-film laminates were prepared and the characteristics thereof were measured and evaluated in the same manner as in Example 1, except that the zinc-oxide-based transparent conductive films (II) had a film thickness of 150 nm (Comparative Example 7), 250 nm (Example 15), 1000 nm (Example 16), and 1050 nm (Comparative Example 8), respectively.

The following Table 2 shows the obtained results. As shown in Table 2, in Comparative Example 7, the film thickness of the zinc-oxide-based transparent conductive film (II) was small, namely 150 nm, whereby crystal particles having a sufficient size were not obtained, and as a result, the surface roughness (Ra) and the haze ratio of the transparent-conductive-film laminate were low, namely 6.3 nm and 4.1%, respectively. Furthermore, in Comparative Example 8, sufficient crystal growth occurred, but, the film thickness of the zinc-oxide-based transparent conductive film (II) was too large, namely 1050 nm, thereby causing a large optical absorption loss, and as a result, the average optical absorptivity in a wavelength range of 400 nm to 600 nm and the average optical absorptivity in a wavelength range of 400 nm to 1200 nm of the transparent-conductive-film laminate were high, namely 15.8% and 15.1%, respectively.

Thus, in Comparative Examples 7 and 8, a transparent-conductive-film laminate having a low optical absorption loss, a high haze ratio, an excellent effect of optical confinement, and a low resistance was not obtained at high speed only by a magnetron sputtering method at low gas pressure. On the other hand, in Examples 15 and 16, as is the case with Example 1, a transparent-conductive-film laminate useful as a surface electrode for solar cells was Ruined.

### Examples 17 to 21

Transparent-conductive-film laminates were prepared and the characteristics thereof were measured and evaluated in the same manner as in Example 1, except that an additive element M contained a target used for preparation of the indium-oxide-based transparent conductive film (I) was changed from Ti to Ga (Example 17), to Mo (Example 18), to Sn (Example 19), to W (Example 20), and to Ce (Example 21), respectively. It should be noted that each of the targets used for preparation of the indium-oxide-based transparent conductive films (I) was quantitatively analyzed by the foregoing evaluation method (1), and the analysis results showed that the targets had an atomic number ratio Ga/(In+Ga) of 0.70 atom % (Example 17), an atomic number ratio Mo/(In+Mo) of 1.00 atom % (Example 18), an atomic number ratio Sn/(In+Sn) of 0.50 atom % (Example 19), an atomic number ratio W/(In+W) of 0.60 atom % (Example 20), and an atomic number ratio Ce/(In+Ce) of 0.80 atom % (Example 21), respectively.

The following Table 2 shows the obtained results. As shown in Table 2, it was confirmed that, in all of Examples 17 to 21, transparent-conductive-film laminates each having a low optical absorption loss, a high haze ratio, an excellent effect of optical confinement, and a low resistance were obtained at high speed only by a magnetron sputtering method at low gas pressure, and furthermore, the transparent-conductive-film laminates were useful as surface electrodes for solar cells.

### Examples 22 to 28

Transparent-conductive-film laminates were prepared and the characteristics thereof were measured and evaluated in the same manner as in Example 1, except that an additive element M contained a target used for preparation of the zinc-oxide-based transparent conductive film (II) was changed from Al and Ga to B (Example 22), to Mg (Example 23), to Si (Example 24), to Ti (Example 25), to Ge (Example 26), to Zr (Example 27), and to Hf (Example 28), respectively. It should be noted that each of the targets used for preparation of the zinc-oxide-based transparent conductive films (II) was quantitatively analyzed by the foregoing evaluation method (1), and the analysis results showed that all of the targets had an atomic number ratio M/(Zn+M) of 0.50 atom % (Examples 22 to 28), where M represents an additive element.

The following Table 2 shows the obtained results. As shown in Table 2, it was confirmed that, in all of Examples 22 to 28, transparent-conductive-film laminates each having a low optical absorption loss, a high haze ratio, an excellent effect of optical confinement, and a low resistance were obtained at high speed only by a magnetron sputtering method at low gas pressure, and furthermore, the transparent-conductive-film laminates were useful as surface electrodes for solar cells.

TABLE 1

| | | | | | | | Deposition condition of transparent | | | |
|---|---|---|---|---|---|---|---|---|---|---|
| | Deposition condition of transparent conductive film (I) | | | | | | conductive film (II) | | | |
| | | Gas | Substrate | | | Film | | Gas | Substrate | Film |
| | Additive | pressure | temperature | H₂O | H₂ | thickness | Additive | pressure | temperature | thickness |
| | element | (Pa) | (° C.) | (Pa) | (Pa) | (nm) | element | (Pa) | (° C.) | (nm) |
| Example 1 | Ti | 0.6 | 25 | — | — | 100 | Al + Ga | 1.0 | 300 | 600 |
| Example 2 | Ti | 0.6 | 50 | — | — | 100 | Al + Ga | 1.0 | 300 | 600 |
| Comparative | Ti | 0.6 | 100 | — | — | 100 | Al + Ga | 1.0 | 300 | 600 |
| Example 1 | | | | | | | | | | |
| Comparative | Ti | — | — | — | — | 0 | Al + Ga | 1.0 | 300 | 600 |
| Example 2 | | | | | | | | | | |
| Example 3 | Ti | 0.6 | 25 | — | — | 10 | Al + Ga | 1.0 | 300 | 600 |
| Example 4 | Ti | 0.6 | 25 | — | — | 250 | Al + Ga | 1.0 | 300 | 600 |
| Comparative | Ti | 0.6 | 25 | — | — | 350 | Al + Ga | 1.0 | 300 | 600 |
| Example 3 | | | | | | | | | | |
| Example 5 | Ti | 0.6 | 25 | 0.007 | — | 100 | Al + Ga | 1.0 | 300 | 600 |
| Example 6 | Ti | 0.6 | 25 | 0.03 | — | 100 | Al + Ga | 1.0 | 300 | 600 |
| Example 7 | Ti | 0.6 | 25 | 0.05 | — | 100 | Al + Ga | 1.0 | 300 | 600 |
| Example 8 | Ti | 0.6 | 25 | — | 0.005 | 100 | Al + Ga | 1.0 | 300 | 600 |
| Example 9 | Ti | 0.6 | 25 | — | 0.02 | 100 | Al + Ga | 1.0 | 300 | 600 |
| Example 10 | Ti | 0.6 | 25 | — | 0.03 | 100 | Al + Ga | 1.0 | 300 | 600 |
| Example 11 | Ti | 0.6 | 25 | — | — | 100 | Al + Ga | 0.5 | 300 | 600 |
| Example 12 | Ti | 0.6 | 25 | — | — | 100 | Al + Ga | 2.0 | 300 | 600 |
| Comparative | Ti | 0.6 | 25 | — | — | 100 | Al + Ga | 2.5 | 300 | 600 |
| Example 4 | | | | | | | | | | |
| Comparative | Ti | 0.6 | 25 | — | — | 100 | Al + Ga | 1.0 | 150 | 600 |
| Example 5 | | | | | | | | | | |
| Example 13 | Ti | 0.6 | 25 | — | — | 100 | Al + Ga | 1.0 | 200 | 600 |
| Example 14 | Ti | 0.6 | 25 | — | — | 100 | Al + Ga | 1.0 | 450 | 600 |
| Comparative | Ti | 0.6 | 25 | — | — | 100 | Al + Ga | 1.0 | 500 | 600 |
| Example 6 | | | | | | | | | | |
| Comparative | Ti | 0.6 | 25 | — | — | 100 | Al + Ga | 1.0 | 300 | 150 |
| Example 7 | | | | | | | | | | |
| Example 15 | Ti | 0.6 | 25 | — | — | 100 | Al + Ga | 1.0 | 300 | 250 |
| Example 16 | Ti | 0.6 | 25 | — | — | 100 | Al + Ga | 1.0 | 300 | 1000 |
| Comparative | Ti | 0.6 | 25 | — | — | 100 | Al + Ga | 1.0 | 300 | 1050 |
| Example 8 | | | | | | | | | | |
| Example 17 | Ga | 0.6 | 25 | — | — | 100 | Al + Ga | 1.0 | 300 | 600 |
| Example 18 | Mo | 0.6 | 25 | — | — | 100 | Al + Ga | 1.0 | 300 | 600 |
| Example 19 | Sn | 0.6 | 25 | — | — | 100 | Al + Ga | 1.0 | 300 | 600 |
| Example 20 | W | 0.6 | 25 | — | — | 100 | Al + Ga | 1.0 | 300 | 600 |
| Example 21 | Ce | 0.6 | 25 | — | — | 100 | Al + Ga | 1.0 | 300 | 600 |
| Example 22 | Ti | 0.6 | 25 | — | — | 100 | B | 1.0 | 300 | 600 |
| Example 23 | Ti | 0.6 | 25 | — | — | 100 | Mg | 1.0 | 300 | 600 |
| Example 24 | Ti | 0.6 | 25 | — | — | 100 | Si | 1.0 | 300 | 600 |
| Example 25 | Ti | 0.6 | 25 | — | — | 100 | Ti | 1.0 | 300 | 600 |
| Example 26 | Ti | 0.6 | 25 | — | — | 100 | Ge | 1.0 | 300 | 600 |
| Example 27 | Ti | 0.6 | 25 | — | — | 100 | Zr | 1.0 | 300 | 600 |
| Example 28 | Ti | 0.6 | 25 | — | — | 100 | Hf | 1.0 | 300 | 600 |

TABLE 2

| | Deposition condition of transparent | | | | | | | | | | |
|---|---|---|---|---|---|---|---|---|---|---|---|
| | conductive film (I) | | | | | Characteristics of transparent-conductive-film laminate | | | | | |
| | | | The | | | | Optical absorptivity | | | | |
| | | | number of | | Zinc- | | (%) | | | | |
| | | | crystals | | oxide-based | | | In a | | | |
| | | | having a | | transparent | | In a | wavelength | | | |
| | | Maximum | diameter | | conductive | | wavelength | range of | | | |
| | Surface | difference in | of | | film (II) | Film | range of 400 nm | 400 nm | Surface | Haze | Resistance |
| | roughness | height | more than | H₂O | H₂ | thickness | to 600 nm | to 1200 nm | roughness | ratio | value |
| | (Ra) (nm) | (Rmax) (nm) | 100 nm | (Pa) | (Pa) | (nm) | (average) | (average) | (Ra) (nm) | (%) | (Ω/sq.) |
| Example 1 | 0.4 | 7.8 | 0 | 100 | 600 | 700 | 9.9 | 9.2 | 38.2 | 16.2 | 9.8 |
| Example 2 | 0.9 | 47.4 | 87 | 100 | 600 | 700 | 9.2 | 8.6 | 31.3 | 9.0 | 11.3 |
| Comparative | 3.2 | 66.4 | 650 | 100 | 600 | 700 | 9.3 | 7.4 | 5.2 | 2.1 | 12.4 |
| Example 1 | | | | | | | | | | | |
| Comparative | — | — | — | 0 | 600 | 600 | 6.0 | 4.4 | 5.0 | 1.8 | 36.3 |
| Example 2 | | | | | | | | | | | |
| Example 3 | 0.3 | 4.3 | 0 | 10 | 600 | 610 | 5.8 | 4.9 | 30.7 | 8.2 | 27.1 |
| Example 4 | 0.8 | 31.5 | 79 | 250 | 600 | 850 | 11.9 | 5.8 | 35.0 | 13.0 | 7.2 |
| Comparative | 1.2 | 54.4 | 112 | 350 | 600 | 950 | 13.7 | 6.7 | 28.2 | 6.0 | 4.3 |
| Example 3 | | | | | | | | | | | |
| Example 5 | 0.3 | 4.4 | 0 | 100 | 600 | 700 | 7.0 | 6.8 | 48.3 | 20.1 | 28.0 |
| Example 6 | 0.3 | 4.4 | 0 | 100 | 600 | 700 | 7.3 | 6.8 | 75.0 | 41.5 | 27.8 |
| Example 7 | 0.4 | 4.4 | 0 | 100 | 600 | 700 | 7.4 | 7.1 | 75.8 | 42.1 | 29.5 |
| Example 8 | 0.3 | 4.9 | 0 | 100 | 600 | 700 | 7.3 | 6.8 | 44.3 | 19.8 | 27.3 |
| Example 9 | 0.3 | 4.4 | 0 | 100 | 600 | 700 | 7.4 | 7.0 | 70.9 | 40.8 | 27.5 |
| Example 10 | 0.3 | 4.4 | 0 | 100 | 600 | 700 | 7.3 | 6.7 | 71.5 | 40.7 | 28.6 |
| Example 11 | 0.5 | 16.2 | 0 | 100 | 600 | 700 | 8.9 | 8.4 | 32.0 | 9.3 | 8.1 |
| Example 12 | 0.4 | 12.2 | 0 | 100 | 600 | 700 | 14.2 | 11.2 | 33.8 | 10.1 | 1.0 |
| Comparative | 0.5 | 14.3 | 0 | 100 | 600 | 700 | 16.3 | 15.3 | 35.6 | 13.3 | 27.9 |
| Example 4 | | | | | | | | | | | |
| Comparative | 0.4 | 8.3 | 0 | 100 | 600 | 700 | 15.1 | 12.8 | 5.3 | 2.3 | 25.9 |
| Example 5 | | | | | | | | | | | |
| Example 13 | 0.4 | 9.8 | 0 | 100 | 600 | 700 | 13.0 | 10.8 | 30.9 | 8.2 | 18.4 |
| Example 14 | 0.4 | 8.9 | 0 | 100 | 600 | 700 | 7.4 | 7.0 | 34.7 | 12.1 | 8.3 |
| Comparative | 0.5 | 11.9 | 0 | 100 | 600 | 700 | 6.0 | 5.8 | 28.9 | 7.6 | 6.9 |
| Example 6 | | | | | | | | | | | |
| Comparative | 0.4 | 9.2 | 0 | 100 | 150 | 250 | 7.1 | 6.5 | 6.3 | 4.1 | 13.6 |
| Example 7 | | | | | | | | | | | |
| Example 15 | 0.4 | 8.3 | 0 | 100 | 250 | 350 | 8.2 | 7.1 | 34.5 | 9.5 | 15.1 |
| Example 16 | 0.4 | 7.9 | 0 | 100 | 1000 | 1100 | 14.5 | 13.9 | 65.8 | 38.2 | 5.1 |
| Comparative | 0.4 | 10.1 | 0 | 100 | 1050 | 1150 | 15.8 | 15.1 | 70.8 | 40.3 | 4.7 |
| Example 8 | | | | | | | | | | | |
| Example 17 | 0.3 | 5.1 | 0 | 100 | 600 | 700 | 8.8 | 8.1 | 34.9 | 12.4 | 12.3 |
| Example 18 | 0.3 | 5.0 | 0 | 100 | 600 | 700 | 9.3 | 8.7 | 34.8 | 12.5 | 10.0 |
| Example 19 | 0.5 | 16.3 | 0 | 100 | 600 | 700 | 10.8 | 9.9 | 33.5 | 10.7 | 8.9 |
| Example 20 | 0.3 | 4.8 | 0 | 100 | 600 | 700 | 9.4 | 9.3 | 35.0 | 12.8 | 9.4 |
| Example 21 | 0.3 | 6.0 | 0 | 100 | 600 | 700 | 9.7 | 9.4 | 34.5 | 11.8 | 11.2 |
| Example 22 | 0.3 | 4.9 | 0 | 100 | 600 | 700 | 10.6 | 9.8 | 37.1 | 14.7 | 10.5 |
| Example 23 | 0.4 | 5.3 | 0 | 100 | 600 | 700 | 9.8 | 9.4 | 38.0 | 15.2 | 10.0 |
| Example 24 | 0.3 | 4.8 | 0 | 100 | 600 | 700 | 9.7 | 9.3 | 34.4 | 12.3 | 11.9 |
| Example 25 | 0.3 | 5.1 | 0 | 100 | 600 | 700 | 10.3 | 9.0 | 37.7 | 15.4 | 10.8 |
| Example 26 | 0.3 | 4.9 | 0 | 100 | 600 | 700 | 10.8 | 9.9 | 37.1 | 15.1 | 11.1 |
| Example 27 | 0.4 | 5.0 | 0 | 100 | 600 | 700 | 11.0 | 10.3 | 35.5 | 13.5 | 12.8 |
| Example 28 | 0.3 | 5.1 | 0 | 100 | 600 | 700 | 9.8 | 8.9 | 34.0 | 10.9 | 13.4 |

### REFERENCE SYMBOLS

1 . . . translucent substrate, 2 . . . transparent-conductive-film laminate, 3 . . . amorphous photoelectric conversion unit, 4 . . . crystalline photoelectric conversion unit, 5 . . . back surface electrode, 21 . . . indium-oxide-based transparent conductive film (I), 22 . . . zinc-oxide-based transparent conductive film (II).

1. A transparent-conductive-film laminate, having a structure, said structure comprising: an indium-oxide-based transparent conductive film (I) with a surface roughness (Ra) of not more than 1.0 nm formed on a translucent substrate; and a zinc-oxide-based transparent conductive film (II) formed on said indium-oxide-based transparent conductive film (I),
wherein the transparent-conductive-film laminate has, as a laminate, a surface roughness (Ra) of not less than 30 nm, a haze ratio of not less than 8%, and a resistance value of not more than 30 Ω/sq., and has an average absorptivity with respect to light in a wavelength range of 400 nm to 1200 nm of not more than 15%.

2. The transparent-conductive-film laminate according to claim 1, wherein the indium-oxide-based transparent conductive film (I) has a maximum difference in surface height (Rmax) of not more than 50 nm.

3. The transparent-conductive-film laminate according to claim 1, wherein not more than 100 projections having a diameter of not more than 100 nm are present per 5 μm square in a surface of the indium-oxide-based transparent conductive film (I).

4. The transparent-conductive-film laminate according to claim 1, the transparent-conductive-film laminate having an average absorptivity with respect to light in a wavelength range of 400 nm to 600 nm of not more than 15%.

5. The transparent-conductive-film laminate according to claim 1, the transparent-conductive-film laminate having a structure comprising: the indium-oxide-based transparent conductive film (I) having a film thickness of not less than 10 nm and not more than 300 nm; and the zinc-oxide-based transparent conductive film (II) having a film thickness of not less than 200 nm and not more than 1000 nm.

6. The transparent-conductive-film laminate according to claim 1, wherein the indium-oxide-based transparent conductive film (I) contains indium oxide as a main component, and contains at least one kind of additive metal element selected from Ti, Ga, Mo, Sn, W, and Ce.

7. The transparent-conductive-film laminate according to claim 1, wherein the zinc-oxide-based transparent conductive film (II) contains zinc oxide as a main component, and contains at least one kind of additive metal element selected from Al, Ga, B, Mg, Si, Ti, Ge, Zr, and Hf.

8. The transparent-conductive-film laminate according to claim 1, wherein the zinc-oxide-based transparent conductive film (II) contains zinc oxide as a main component, and contains at least one kind of additive metal element selected from Al and Ga at an atomic number ratio (Al+Ga)/(Zn+Al+Ga) of 0.3 to 6.5 atom % and at an atomic number ratio Al/(Al+Ga) of 30 to 70 atom %.

9. A manufacturing method for a transparent-conductive-film laminate, comprising:
a first deposition step of forming an indium-oxide-based transparent conductive film (I) having a film thickness of not less than 10 nm and not more than 300 nm on a translucent substrate by a sputtering method under conditions of a gas pressure of not less than 0.1 Pa and not more than 2.0 Pa and a substrate temperature of not more than 50° C.; and
a second deposition step of forming a zinc-oxide-based transparent conductive film (II) having a film thickness of not less than 200 nm and not more than 1000 nm on the indium-oxide-based transparent conductive film (I) by a sputtering method under conditions of a gas pressure of not less than 0.1 Pa and not more than 2.0 Pa and a substrate temperature of not less than 200° C. and not more than 450° C.

10. The manufacturing method for a transparent-conductive-film laminate according to claim 9, wherein, in the first deposition step, H₂O gas is introduced, and an indium-oxide-based transparent conductive film (I) is deposited under an atmosphere having an H₂O partial pressure of not more than 0.05 Pa.

11. The manufacturing method for a transparent-conductive-film laminate according to claim 9, wherein, in the first deposition step, H₂ gas is introduced, and an indium-oxide-based transparent conductive film (I) is deposited under an atmosphere having an H₂ partial pressure of not more than 0.03 Pa.

12. The manufacturing method for a transparent-conductive-film laminate according to claim 9, wherein a sputtering target used for forming the zinc-oxide-based transparent conductive film (II) contains zinc oxide as a main component, and contains at least one kind of additive metal element selected from Al and Ga at an atomic number ratio (Al+Ga)/(Zn+Al+Ga) of 0.3 to 6.5 atom % and at an atomic number ratio Al/(Al+Ga) of 30 to 70 atom %.

13. A thin-film solar cell, including:
a translucent substrate; and
a transparent-conductive-film laminate, a photoelectric conversion layer unit, and a back surface electrode layer formed in that order on the translucent substrate,
wherein the transparent-conductive-film laminate
has a structure including: an indium-oxide-based transparent conductive film (I) with a surface roughness (Ra) of not more than 1.0 nm formed on the translucent substrate; and a zinc-oxide-based transparent conductive film (II) formed on said indium-oxide-based transparent conductive film (I), and
has, as a laminate, a surface roughness (Ra) of not less than 30 nm, a haze ratio of not less than 8%, and a resistance value of not more than 30 Ω/sq., and has an average absorptivity with respect to light in a wavelength range of 400 nm to 1200 nm of not more than 15%.

14. A manufacturing method for a thin-film solar cell,
the thin-film solar cell including:
a translucent substrate; and
a transparent-conductive-film laminate, a photoelectric conversion layer unit, and a back surface electrode layer formed in that order on the translucent substrate,
wherein the transparent-conductive-film laminate is formed by a transparent-conductive-film laminate formation step, the transparent-conductive-film laminate formation step including:
a first deposition step of forming an indium-oxide-based transparent conductive film (I) having a film thickness of not less than 10 nm and not more than 300 nm on the translucent substrate by a sputtering method under conditions of a gas pressure of not less than 0.1 Pa and not more than 2.0 Pa and a substrate temperature of not more than 50° C.; and
a second deposition step of forming a zinc-oxide-based transparent conductive film (II) having a film thickness of not less than 200 nm and not more than 1000 inn on the indium-oxide-based transparent conductive film (I) by a sputtering method under conditions of a gas pressure of not less than 0.1 Pa and not more than 2.0 Pa and a substrate temperature of not less than 200° C. and not more than 450° C.
